(19) United States
(12) Patent Application Publication
(10) Pub. No.: US 2013/0193516 A1
(43) Pub. Date: Aug. 1, 2013

(54) SRAM INTEGRATED CIRCUITS AND METHODS FOR THEIR FABRICATION

(71) Applicants: Matthias Goldbach, Dresden (DE); Peter Baars, Dresden (DE)

(72) Inventors: Matthias Goldbach, Dresden (DE); Peter Baars, Dresden (DE)

(73) Assignee: GLOBALFOUNDRIES INC., Grand Cayman (KY)

(21) Appl. No.: 13/359,242

(22) Filed: Jan. 26, 2012

(51) Int. Cl. H01L 27/11; H01L 21/762; H01L 21/336

(52) U.S. Cl. 257/368; 438/197; 438/424; 257/E27.098; 257/E21.546

(57) ABSTRACT

SRAM ICs and methods for their fabrication are provided. One method includes forming dummy gate electrodes overlying a semiconductor substrate and defining locations of gate electrodes for two cross coupled inverters and two pass gate transistors. A first insulating layer is deposited overlying the dummy gate electrodes and gaps between the dummy gate electrodes are filled with a second insulating layer. The second insulating layer is etched to form inter-gate openings exposing portions of the substrate. The first insulating layer is etched to reduce the thickness of selected locations thereof, and the dummy gate electrodes are removed. A gate electrode metal is deposited and planarized to form gate electrodes and local interconnections coupling the gate electrodes of one inverter to a node between the pull up and pull down transistors of the other inverter and to a source/drain of one of the pass gate transistors.

### TECHNICAL FIELD

The present invention generally relates to SRAM integrated circuits and to methods for their fabrication, and more particularly relates to SRAM integrated circuits fabricated with a reduced number of metal layers and to methods having reduced complexity for fabricating such SRAM integrated circuits.

### BACKGROUND

Static random access memory (SRAM) integrated circuits (ICs) are widely used, both as stand alone memories and as embedded memories in, for example, microprocessors. The size of such SRAM ICs has increased markedly so that memories in excess of one million bits are now common. As IC size has increased, so has the processing complexity. The increased IC size requires a reduction in the size of individual components and in the minimum feature size, the minimum width of lines and spaces within an individual component. Processing complexity increases as the feature size decreases because it becomes difficult to precisely define lines and to insure adequate spacing between features on different processing levels.

The industry standard SRAM cell includes six transistors and requires three levels of metal in addition to the gate electrode level. Reliably processing the multiple layers of conductors and the necessary contacts to those conductor levels is difficult, especially when the minimum feature size shrinks to the range of 20 nanometers (nm) or less.

Accordingly, it is desirable to provide an SRAM integrated circuit having reduced levels of interconnection. In addition, it is desirable to provide methods for fabricating SRAM integrated circuits with reduced complexity and hence increased reliability. Furthermore, other desirable features and characteristics of the present invention will become apparent from the subsequent detailed description and the appended claims, taken in conjunction with the accompanying drawings and the foregoing technical field and background.

### BRIEF SUMMARY

Methods are provided for fabricating an SRAM integrated circuit. In accordance with one embodiment, dummy gate electrodes are formed overlying a semiconductor substrate, the dummy gate electrodes defining locations of gate electrodes for two pull up transistors, two pull down transistors, and two pass gate transistors. A first insulating layer is deposited overlying the dummy gate electrodes and gaps between the dummy gate electrodes are filled with a second insulating layer. The second insulating layer is selectively etched to form inter-gate openings exposing selected portions of the semiconductor substrate. The first insulating layer is selectively etched to reduce the thickness of a selected location thereof and the dummy gate electrodes are removed. A gate electrode metal is deposited and planarized to replace the dummy gate electrodes and to form gate electrodes and local interconnections coupling the gate electrodes of one of the pull up transistors and one of the pull down transistors to a node between the other of the pull up transistors and pull down transistors and to a source/drain of one of the pass gate transistors

In accordance with a further embodiment, dummy gate electrodes are formed overlying a semiconductor substrate, the dummy gate electrodes defining locations of gate electrodes for two pull up transistors, two pull down transistors, and two pass gate transistors. A layer of insulating material is deposited overlying the dummy gate insulators and openings are etched through the layer of insulating material at selected locations between the dummy gate electrodes. The dummy gate electrodes are removed and a conductive material is deposited to replace the dummy gate electrodes and fill the openings. The conductive material is planarized to form gate electrodes and interconnections coupling at least: a first of the pull up transistors to a first of the pull down transistors at a first node, the gate electrode of the first pull up transistor to the gate electrode of the first pull down transistor, and gate electrodes of a second of the pull up transistors and pull down transistors to the first node.

An SRAM integrated circuit is also provided that includes a first pull up transistor and a first pull down transistor each having a first common gate electrode formed of a conductive layer and coupled at a first node by the conductive layer. The IC also includes a second pull up transistor and a second pull down transistor each having a second common gate electrode formed of the conductive layer and coupled at a second node by the conductive layer, a first pass gate transistor having a third gate electrode formed of the conductive layer and coupled to the first node by the conductive layer, and a second pass gate transistor having a fourth gate electrode formed of the conductive layer and coupled to the second node by the conductive layer. A first connection formed of the conductive layer extends between the first common gate electrode and the second node, and a second connection formed of the conductive layer extends between the second common gate electrode and the first node

### BRIEF DESCRIPTION OF THE DRAWINGS

The present invention will hereinafter be described in conjunction with the following drawing figures, wherein like numerals denote like elements, and wherein:

FIG. 1 illustrates a conventional six transistor SRAM cell;

FIGS. 2-4 illustrate conventional photo masks used in fabricating a conventional SRAM cell;

FIGS. 5-7 and 10-13 schematically illustrate, in cross sectional views, an improved SRAM IC and method steps for its fabrication in accordance with various embodiments; and

FIGS. 8, 9, and 14-16 illustrate photo mask used in fabricating the improved SRAM IC.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

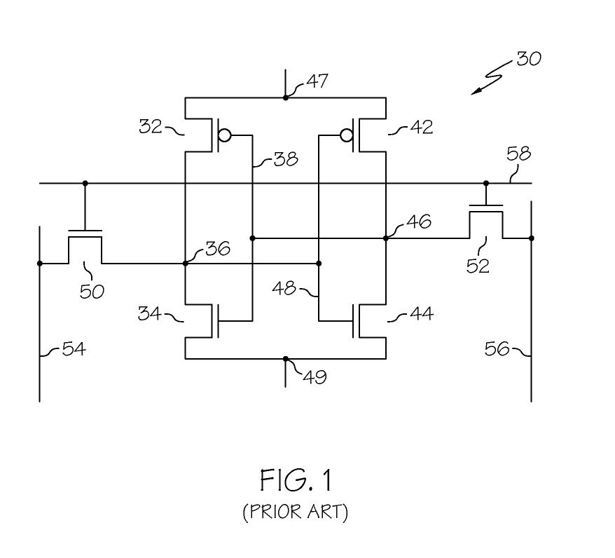

FIG. 1 is a circuit schematic for the industry standard six transistor static random access memory (SRAM) cell 30. In an SRAM integrated circuit (IC) such a cell would be reproduced many times in a regular array of rows and columns. The standard cell is produced with metal oxide semiconductor field effect transistors (MOSFETs) or simply MOS transistors or FETs. An MOS transistor includes a gate electrode as a control electrode and spaced apart source and drain regions formed in a semiconductor substrate and between which a current can flow. A control voltage applied to the gate electrode controls the flow of current through a channel between the source and drain regions. The gate electrode is electrically insulated from the underlying channel by a gate dielectric. Such MOS transistors can be P-channel (PMOS) or N-channel (NMOS).

SRAM cell 30 includes two cross coupled inverters. The first inverter includes a PMOS pull up transitor 32 and an NMOS pull down transistor 34 joined at a common node 36. Transistors 32 and 34 have a common gate connection 38. The second inverter likewise includes a PMOS pull up transitor 42 and an NMOS pull down transistor 44 joined at a common node 46. Transistors 42 and 44 have a common gate connection 48. Cross coupling of the two inverters is accomplished by coupling common gate 38 to node 46 and by coupling common gate 48 to node 36. The sources of pull up transistors 32 and 42 are coupled to a first potential source 47, usually V_{DD} and the sources of pull down transistors 34 and 44 are coupled to a second potential source 49, usually V_{SS} or ground. The cell is accessed for reading or writing by NMOS pass gate transistors 50 and 52. Pass gate transistor 50 is coupled between a bit line (BL) 54 and common node 36. Pass gate transistor 52 is coupled between a complementary bit line (BLB) 56 and common node 46. The gates of pass gate transistors 50 and 52 are coupled to a word line (WL) 58.

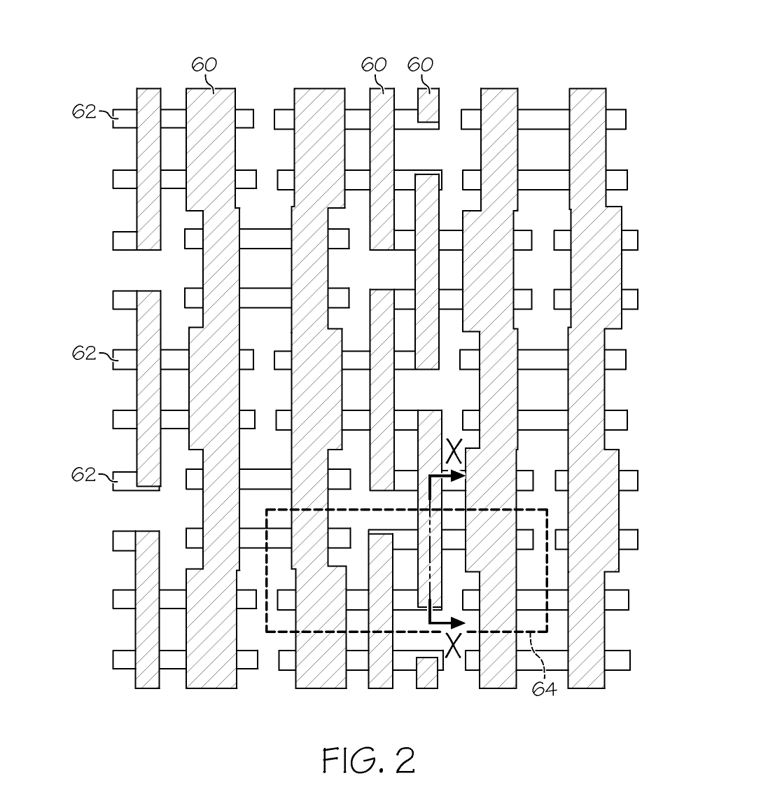

As is well known, integrated circuits such as SRAM integrated circuits are formed in and on a semiconductor substrate with the fabrication process involving a series of photolithographic processing steps in which a layer of photosensitive material is exposed to radiation that passes through a photo mask to transfer images on the photo mask to the layer of photosensitive material. The layer of photosensitive material is then developed and the resulting patterned mask is used as a process mask for an etching, ion implantation, or other process step. The problems associated with the conventional fabrication of SRAM ICs is best illustrated by looking at a number of the photo mask layers needed for such fabrication and their interrelation as illustrated in FIGS. 2-4.

FIG. 2 illustrates the overlay of two photo masks 60 and 62. Photo mask 60 defines the active semiconductor regions of the IC and photo mask 62 defines the gate electrode layer of a conventional SRAM IC. One bit of the SRAM array is indicated by the rectangular box 64.

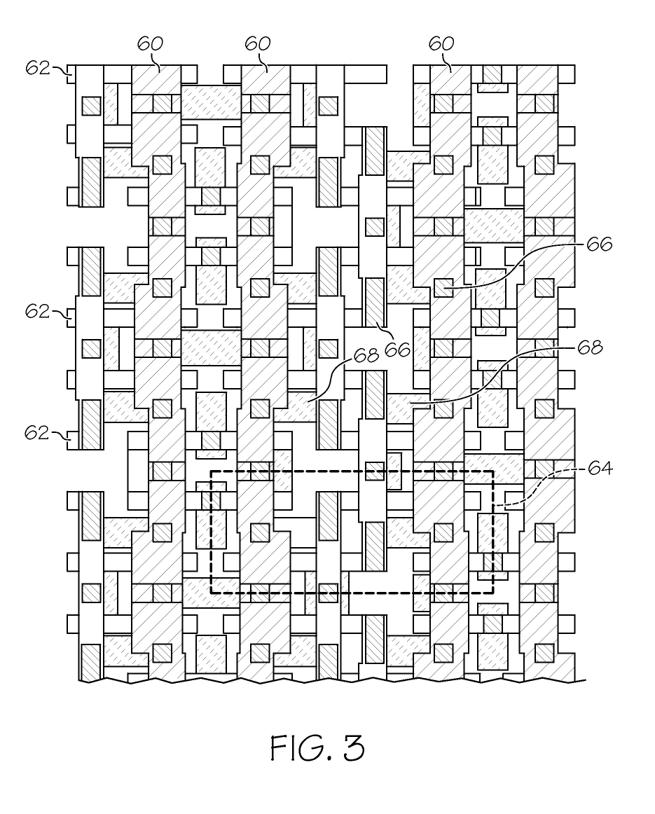

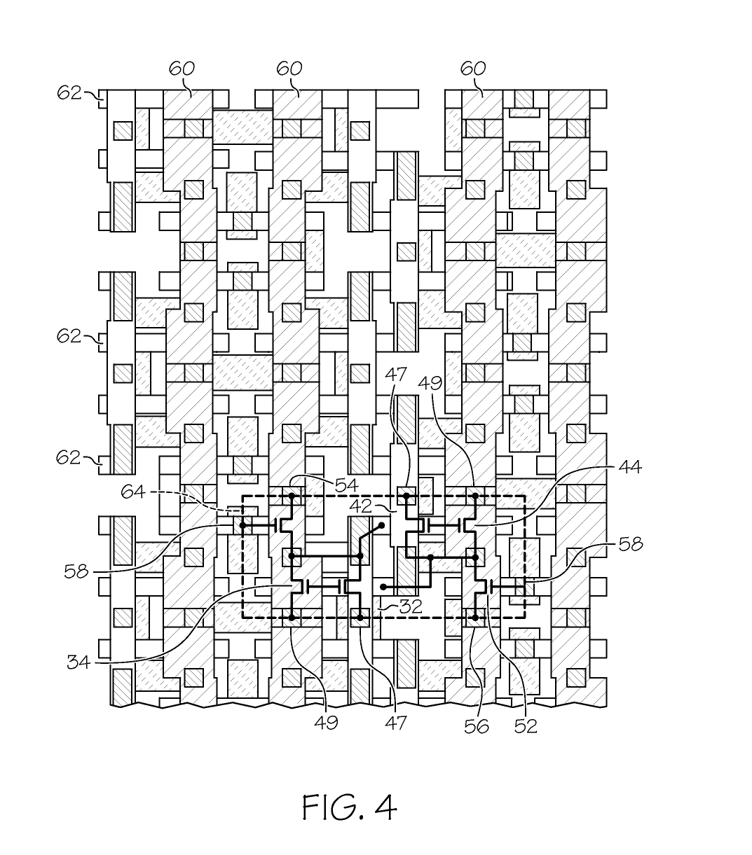

FIG. 3 illustrates the addition of two additional photo masks to those illustrated in FIG. 2. Photo mask 66 provides contact openings and photo mask 68 defines a first metal layer, usually referred to as metal one or M1. For convenience, FIG. 4 shows the same photo mask layers with the standard six transistor SRAM cell layout superimposed. The squares of photo mask 66 provide contact between semiconductor regions and metal one. The rectangles of photo mask 66 provide contact between metal one and both the active semiconductor regions and the gate electrode layer. Subsequent mask layers (not illustrated) are used to pattern metal layer two (M2) and metal layer three (M3). Metal layer two provides, for example, V_{DD} and the bit lines (BL and BLB) to the cell and metal layer three provides, for example, V_{SS} and the word lines (WL) to the cell. Thus in the conventional approach three levels of metal are needed above the gate level to complete the SRAM cell. In addition, the contacts of photo mask 66 must be etched through two different thickness of insulator because they make contact to the cell at different levels (gate electrode level and active silicon level). The SRAM layout is very dense, and correctly etching the contacts is critical to the fabrication process of those levels. As the feature size is reduced, it becomes more and more difficult to correctly and reliably etch the contacts. Metal layer one is typically used for local connections in the SRAM cell and for wiring through to metal layer two. An additional layer of metallization in the SRAM cell, metal layer one, increases restrictions on overlay and on critical dimensions of the layer and therefore increases the complexity of the fabrication process.

An improved SRAM IC 100 and methods for fabricating such an IC, in accordance with various embodiments thereof, are illustrated in FIGS. 5-16. The new SRAM IC uses the same standard six transistor SRAM cell as that illustrated in FIG. 1, but the IC is implemented with one less level of metallization and with a simplified contact structure. Various steps in the fabrication of MOS semiconductor devices are well known and so, in the interest of brevity, many conventional steps will only be mentioned briefly herein or will be omitted entirely without providing the well-known process details. While the term “MOS” properly refers to a device having a metal gate electrode overlying an oxide gate insulator, that term will be used herein to refer to any device having a gate electrode, whether metal or other conductive material, overlying a gate insulator, whether oxide or other dielectric material, which overlies a semiconductor substrate.

In accordance with one embodiment, the method for fabricating SRAM IC 100 begins with the same photo mask layers as illustrated in FIG. 2. Again, mask layers 60 and 62 define the active semiconductor regions and the gate electrode layer, respectively. The active semiconductor regions are separated from each other by isolation regions such as shallow trench isolation. In accordance with this embodiment photo mask layer 62 is used to pattern a dummy gate electrode structure that will subsequently be replaced by an actual gate electrode structure as will be explained below. The dummy gate electrodes define locations of gate electrodes for two pull up transistors 32 and 42, two pull down transistors 34 and 44, and two pass gate transistors 50 and 52. The dummy gate electrodes, in accordance with one embodiment, are substantially straight line structures aligned in a substantially parallel array.

FIG. 5 illustrates, in cross section, a portion of SRAM IC 100 after the application of photo masks 60 and 62. The cross section is taken along the line X-X in FIG. 2. Fabrication of SRAM IC 100 begins by providing a semiconductor substrate 102. Semiconductor substrate 102 can be, for example, silicon, silicon admixed with other elements such as germanium or carbon, or other semiconductor material. Semiconductor substrate 102 may be referred to herein, for simplicity but without limitation, either as a semiconductor substrate or as a silicon substrate. Silicon substrate 102 can be a bulk silicon wafer or a silicon on insulator (SOI) wafer. Active regions in the semiconductor substrate are delineated by photo mask 60, and isolation regions 104, such as STI regions, are formed to electrically isolate unrelated regions. The active regions are doped with conductivity-determining impurities to form P-doped and N-doped wells for the fabrication of NMOS transistors and PMOS transistors, respectively.

In accordance with one embodiment, a layer of high dielectric constant (high-k) gate insulator 106 is deposited or otherwise formed overlying semiconductor substrate 102. High-k gate insulator 106 can be, for example, a layer of hafnium oxide which may be layered with a layer of silicon oxide or other insulator. A layer of titanium nitride 108 is deposited over the gate insulator, and a layer of dummy gate electrode material 110 such as a layer of polycrystalline silicon is deposited over the layer of titanium nitride. The layer of dummy gate electrode material, layer of titanium nitride, and layer of gate insulator are patterned to form dummy gates 112 using photo mask 62 as an etch mask to pattern the dummy gate structure. Conventional processing steps are used to form source and drain regions 114 in the active semiconductor regions, for example by the implantation of conductivity-determining dopant ions using the dummy gate electrodes as ion implantation masks. As is well known, sidewall spacers (not illustrated) may also be used as part of the ion implantation mask. In the illustrated cross section, only P-type source/drain regions of pull up transistor 32 and 42 are shown.

A conformal layer of an insulating material 116 such as a layer of silicon nitride is deposited overlying the dummy gates and the semiconductor substrate as illustrated in FIG, 6. A layer of another insulator 118, different than insulator 116, such as a layer of silicon oxide, is deposited over insulator layer 116 to a sufficient thickness to fill the gaps or spaces between adjacent dummy gate electrodes 112. Insulator layer 118 is planarized, for example by chemical mechanical planarization (CMP), to expose insulator layer 116 where it overlies a dummy gate electrode.

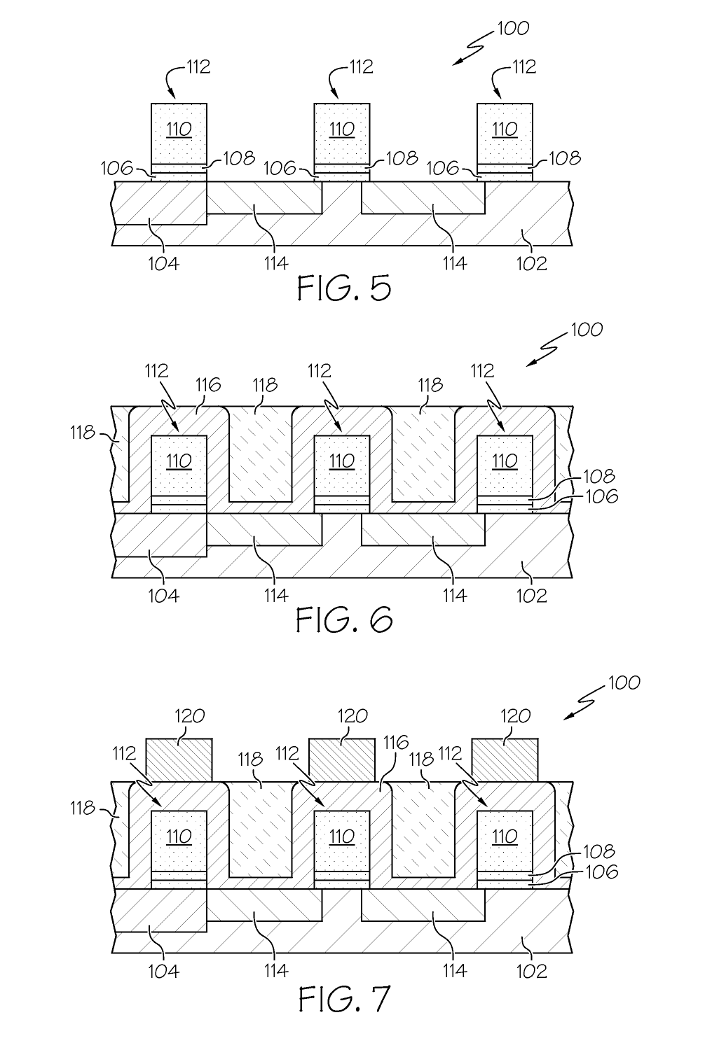

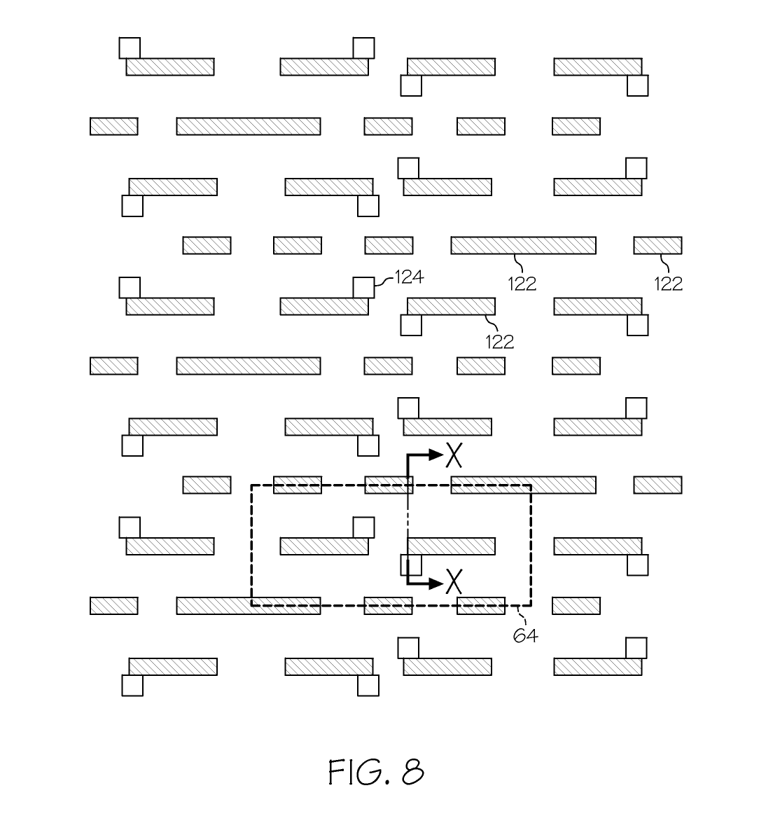

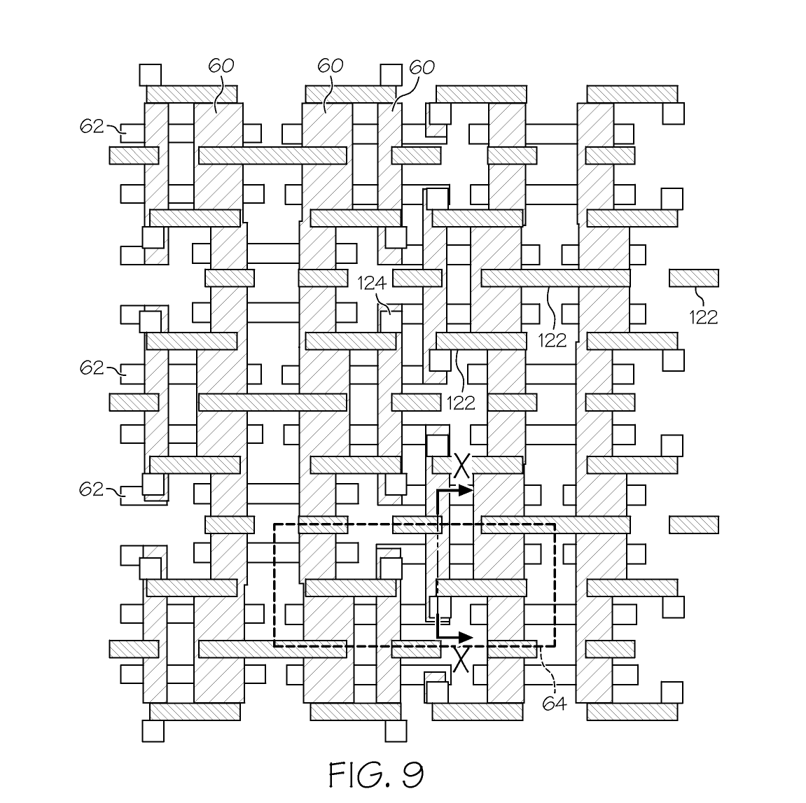

The method for fabricating SRAM IC 100 continues, in accordance with one embodiment, by depositing and patterning a layer of hard mask material 120 overlying the planarized surface of insulator layer 118 and the exposed portion of insulator layer 116 as illustrated in FIG. 7. Hard mask material 120 is patterned with an inter-gate photo mask 122 as illustrated in FIG. 8. FIG. 8 also illustrates, as an overlay, an additional photo mask 124. Photo mask 124 is a spacer-cut mask, the use of which will be explained below. The positioning of photo masks 122 and 124, relative to photo masks 60 and 62 is illustrated in FIG. 9 which is an overlay of the four photo masks 60, 62, 122 and 124.

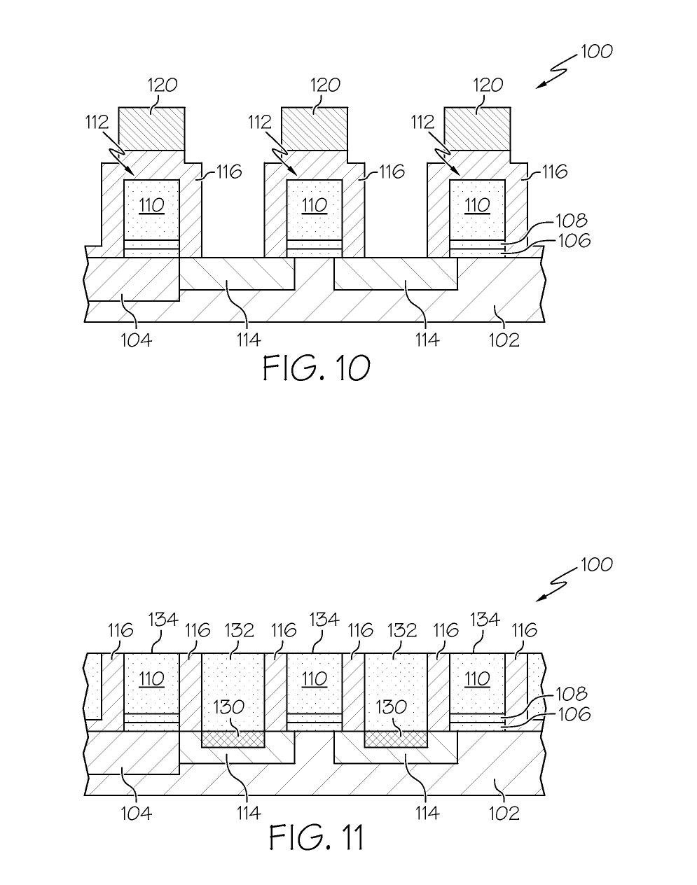

As illustrated in FIG. 10, patterned hard mask layer 120 is used as an etch mask and insulator layer 118 is etched to form inter-gate openings and thereby selectively expose portions of semiconductor substrate 102 including portions of the surface of source and drain regions 114 and STI region 104 at locations between the dummy gate insulators. In accordance with one embodiment the inter-gate openings are substantially straight line openings parallel to and spaced between adjacent ones of the dummy gate electrodes. The positioning of the exposed portions can be seen by considering the overlay of photo masks in FIG. 9. The alignment of inter-gate photo mask 122 is not critical because the use of two different insulator materials for insulator layers 116 and 118 makes this a self-aligned etch step. This etching step is thus highly reliable which is important for a high yielding method. Partial etching of insulator layer 116 is acceptable as long as dummy gate electrodes 112 remain encapsulated.

Following the etching of insulator layer 118 using patterned hard mask layer 120 as an etch mask, the hard mask is removed. If the semiconductor substrate is a silicon rich material, a layer of metal silicide forming metal is deposited and heated to react the metal with any silicon exposed through the inter-gate openings such as the silicon in source/drain regions 114. Heating the metal in contact with silicon causes the formation of metal silicide in the contacts 130 as illustrated in FIG. 11. The metal can be, for example, nickel or nickel and platinum to form nickel or nickel-platinum silicide. After forming the metal silicide, a fill material 132 such as polycrystalline silicon is deposited and planarized to fill the spaces between the dummy gate electrodes; i.e., to fill the inter-gate openings formed by etching using photo mask 122. The planarization, for example done by CMP, is continued to expose the top surfaces 134 of dummy gate electrodes 112.

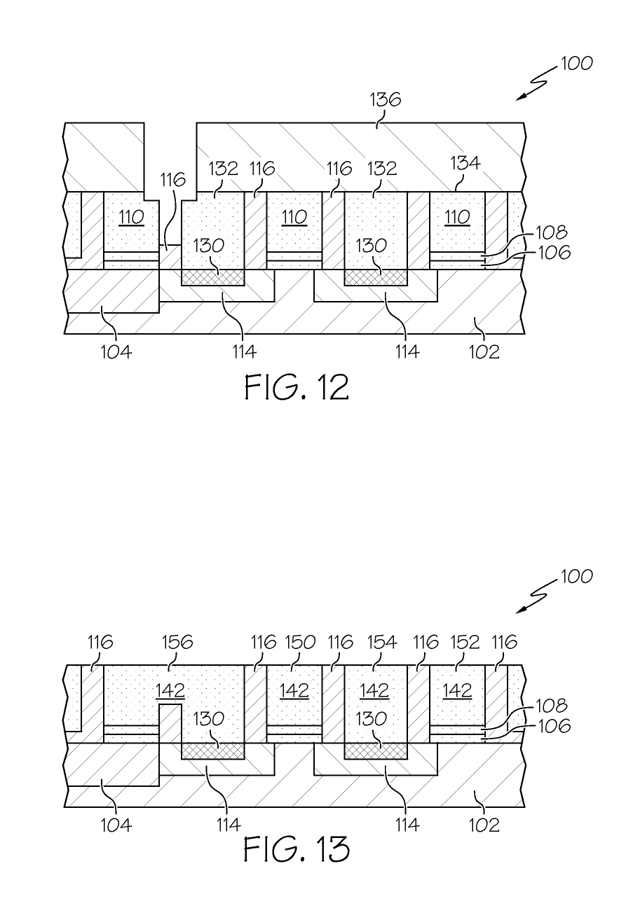

A further hard mask layer 136 is deposited overlying the planarized surface and is patterned using spacer-cut mask 124 as illustrated in FIG. 12. The patterned hard mask layer is used together with the planarized fill material as an etch mask and the thickness of the exposed portion of insulator layer 116 is reduced. The insulator layer is etched with an etchant that etches the insulator layer material (e.g., silicon nitride) at a faster rate than the etch rate of fill material 132 or dummy gate electrode material (e.g, polycrystalline silicon). It is not harmful, however, if some etching of the fill material or the dummy gate material occurs as those material will subsequently be removed. Etchants that are highly selective to silicon nitride compared to polycrystalline silicon are readily available, so the thickness of the exposed insulator layer 116 can be controlled with high accuracy. The final thickness of the recessed insulator layer can be freely chosen and can be, for example about 15% to about 30% of the thickness of dummy gate electrode 112.

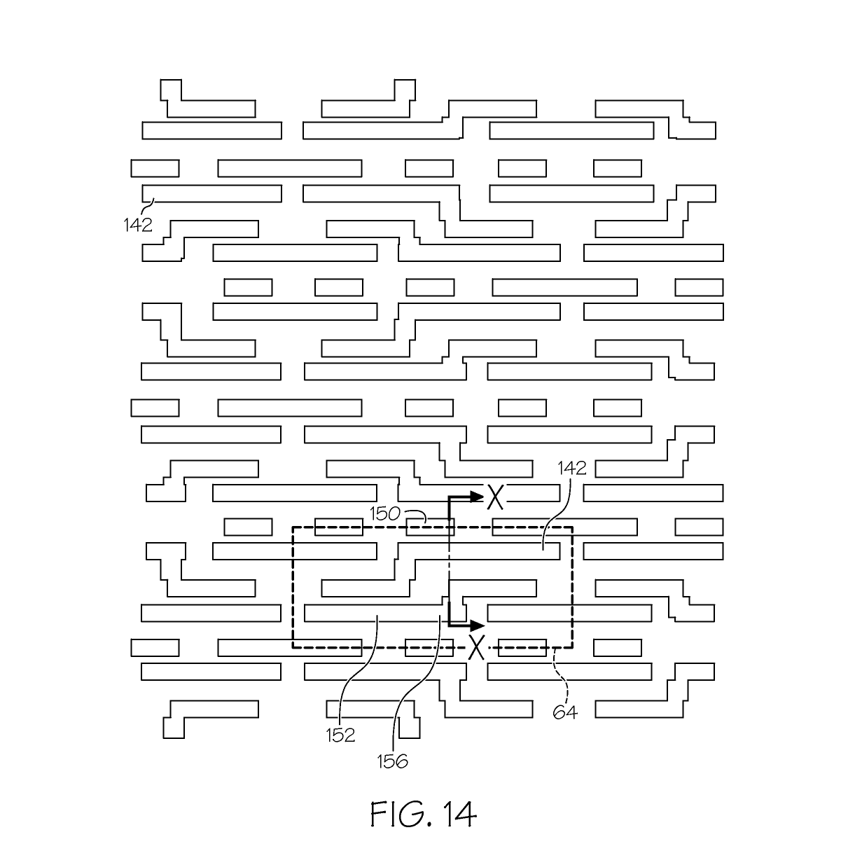

In accordance with one embodiment, after reducing the thickness of selected portions of insulator layer 116, hard mask layer 136, fill material 132, and the dummy gate electrode material 110 are all removed as illustrated in FIG. 13. Layer of titanium nitride 108 and high-k gate insulator layer 106 remain in the gate locations in this hybrid gate-last embodiment. Generically, a work function determining material and a gate electrode material, together denoted by 142, are deposited overlying the layer of titanium nitride and the exposed metal silicide contacts 130 and the recessed portion of insulator layer 116 to fill the voids left by the removal of the gate electrode material and the fill material and are planarized to form at least: gate electrodes such as gate electrodes 150 and 152; source/drain contacts 154; contacts 156 to nodes 36 and 46 that couple the pass gate transistors, common node between pull up and pull down transistors, and cross coupled gate electrodes; and contacts for coupling the pull up transistors to a potential node (V_{DD}) and the pull down transistors to another potential node (V_{SS}). The gate electrode material thus forms local interconnects that: couple the gate electrodes of each pull up transistor to its associated pull down transistor to form a common gate electrode; couple each pull up transistor to its associated pull down transistor at a common inverter node; couple the common gate electrode to the common inverter node between the pull up and pull down transistors of the opposite inverter pair; couple the source/drain of the pass gate transistors to the common inverter nodes; and provide for the SRAM cell to be coupled to potential sources V_{DD} and V_{SS}. In addition, gate electrode material 142 provides contacts to the pass gate transistor to which the bit lines and word lines are subsequently coupled. In accordance with one embodiment the work function determining material and gate electrode material are deposited as follows. After removing the dummy gate electrode material, layer of titanium nitride 108 overlying high-k gate insulator layer 106 is exposed. A layer of tantalum nitride is deposited over the layer of titanium nitride, and a capping layer of titanium nitride is deposited over the layer of tantalum nitride. Following a heat treatment, the PMOS transistors are masked, for example with photoresist, and the NMOS transistors are exposed. The capping layer of titanium nitride is removed from the NMOS transistors by etching with a wet etchant that stops on the tantalum nitride. The photoresist mask is removed and the void left by the removal of the dummy gate electrode material is filled with a titanium/aluminum fill. The fill material is reflowed by heating and then is planarized, for example by CMP, to remove the fill material overlying the remaining portion of insulator layer 116. Notably the SRAM cell is thus fabricated with only one layer of metal as illustrated in top view in FIG. 14, the gate electrode forming metal, which serves as both the gate electrode metal and as the local interconnect replacing the formerly used metal one (M1). Additionally, contacts to nodes 36 and 46 as well as to source/drain regions are made by vias that are all of the same size and all etched through the same intervening layers.

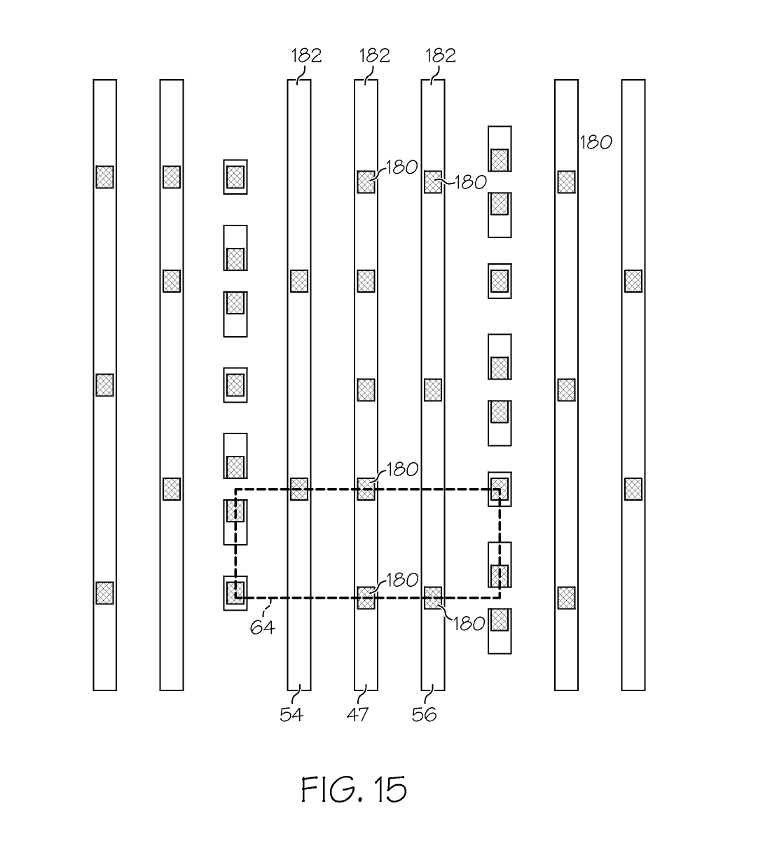

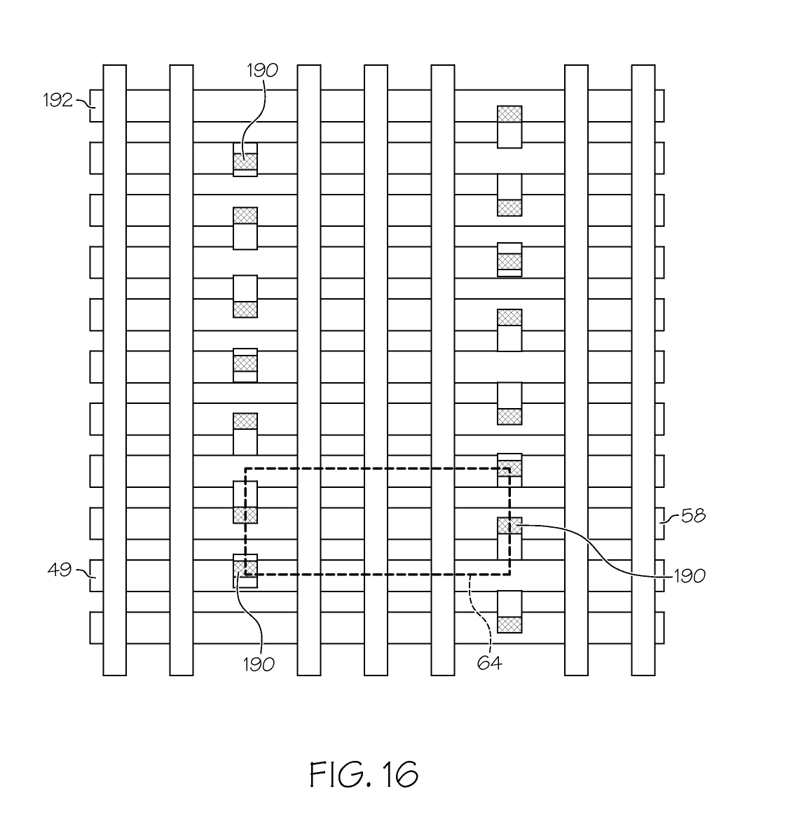

Fabrication of SRAM IC 100 continues as illustrated in FIGS. 15 and 16. FIG. 15 illustrates a composite overlay of two photo masks 180 and 182. Photo mask 180 is a via mask and photo mask 182 is a mask for patterning what, in this new method, is now metal one. A layer of insulating material (an inter-layer dielectric or ILD) is deposited overlying the structure illustrated in FIG. 13. Openings or vias are etched through the ILD using photo mask 180 to selectively expose portions of gate material layer 142. A layer of metal such as a layer of copper is deposited overlying the ILD and extending into the vias defined by photo mask 180 and is patterned using photo mask 182. The layer of metal can be patterned by a subtractive process or by a damascene process. The resulting metal one pattern is defined by photo mask 182 and forms bit lines 54 and complementary bit lines 56 as well as V_{DD} lines 47. The bit lines and complementary bit lines are coupled to contacts formed of gate material 142 on pass gate transistors 50 and 52, respectively. The V_{DD} lines are coupled to contacts formed of gate material 142 on the pull up transistors 32 and 42.

FIG. 16 illustrates a composite overlay of two additional photo masks 190 and 192 in addition to photo mask 182. Photo mask 190 is a via mask and photo mask 192 is a mask for patterning what, in this new method, is metal two. A layer of ILD is deposited overlying metal layer one and is patterned using photo mask 190 to selectively expose portions of metal one. A layer of metal such as a layer of copper is deposited overlying the ILD and extending into the vias defined by photo mask 190 and is patterned using photo mask 192. Again, the layer of metal can be patterned by a subtractive process or by a damascene process. The resulting metal twp pattern is defined by photo mask 192 and forms word lines 58 coupled to contacts formed of metal layer 142 on pass gate transistors 50 and 52 and V_{SS} lines 49 coupled to contacts formed of metal layer 142 on pull down transistors 34 and 44. The memory array portion of SRAM IC 100 is thus fabricated with only two metal layers above the gate layer instead of the conventional three layers. Those of skill in the art will understand that additional processing steps may be implemented in the fabrication of the subject SRAM IC, but to describe and illustrate those well-known steps would only obscure the significance of the steps that have been described and illustrated.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the invention in any way. Rather, the foregoing detailed description will provide those skilled in the art with a convenient road map for implementing the exemplary embodiments. It should be understood that various changes can be made in the function and arrangement of elements without departing from the scope of the invention as set forth in the appended claims and the legal equivalents thereof

1. A method for fabricating an SRAM integrated circuit comprising:
forming dummy gate electrodes overlying a semiconductor substrate, the dummy gate electrodes defining locations of gate electrodes for two pull up transistors, two pull down transistors, and two pass gate transistors;
depositing a first insulating layer overlying the dummy gate electrodes;
filling gaps between the dummy gate electrodes with a second insulating layer;
selectively etching the second insulating layer to form inter-gate openings exposing selected portions of the semiconductor substrate;
selectively etching the first insulating layer to reduce the thickness of a selected location thereof;
removing the dummy gate electrodes;
depositing and planarizing a gate electrode material to replace the dummy gate electrodes and to fill the inter-gate openings to form gate electrodes and local interconnections coupling the gate electrodes of one of the pull up transistors and one of the pull down transistors to a node between the other of the pull up transistors and pull down transistors and to a source/drain of one of the pass gate transistors.

2. The method of claim 1 further comprising forming a layer of high dielectric constant gate insulator underlying the dummy gate electrodes.

3. The method of claim 1 wherein depositing a first insulating layer comprises depositing a layer of silicon nitride and wherein filling gaps with a second insulating layer comprises depositing a layer of silicon oxide.

4. The method of claim 3 wherein selectively etching the second insulating layer comprises:
planarizing the layer of silicon oxide;
depositing and patterning a layer of hard mask material overlying the planarized layer of silicon oxide;
etching the layer of silicon oxide using the patterned layer of hard mask material to form inter-gate openings through the layer of silicon oxide positioned between adjacent ones of the dummy gate electrodes.

5. The method of claim 1 wherein the semiconductor substrate comprises a silicon substrate, and wherein the method further comprising forming metal silicide contacts in portions of the silicon substrate exposed through the inter-gate openings.

6. The method of claim 5 further comprising depositing and planarizing a fill material filling the inter-gate openings.

7. The method of claim 6 wherein selectively etching the first insulating layer comprises:
forming a patterned hard mask layer overlying the planarized fill material and exposing a selected location thereof; and
selectively etching the first insulating layer using the patterned hard mask layer and the planarized fill material as an etch mask.

8. The method of claim 7 wherein removing the dummy gate electrodes further comprises removing the planarized fill material.

9. The method of claim 8 wherein depositing and planarizing a gate electrode material comprises depositing aluminum overlying the metal silicide and extending across the selected location to a gate electrode.

10. A method for fabricating an SRAM integrated circuit comprising:
forming dummy gate electrodes overlying a semiconductor substrate, the dummy gate electrodes defining locations of gate electrodes for two pull up transistors, two pull down transistors, and two pass gate transistors;
depositing a layer of insulating material overlying the dummy gate insulators;
etching openings through the layer of insulating material at selected locations between the dummy gate electrodes;
removing the dummy gate electrodes;
depositing a conductive material replacing the dummy gate electrodes and filling the openings; and
planarizing the conductive material to form gate electrodes and interconnections coupling at least: a first of the pull up transistors to a first of the pull down transistors at a first node, the gate electrode of the first pull up transistor to the gate electrode of the first pull down transistor, and gate electrodes of a second of the pull up transistors and pull down transistors to the first node.

11. The method of claim 10 wherein the dummy gate electrodes comprise a plurality of parallel, substantially straight line structures, and wherein etching openings comprises etching substantially straight line openings parallel to and spaced between adjacent ones of the dummy gate electrodes.

12. The method of claim 10 wherein the semiconductor substrate comprises silicon and wherein the method further comprises forming metal silicide contacts in portions of the semiconductor substrate exposed through the openings.

13. The method of claim 12 further comprising forming a recessed portion of insulating material between selected ones of the metal silicide contacts and selected ones of the dummy gate electrodes.

14. The method of claim 13 wherein depositing a conductive material comprises depositing a metal overlying the recessed portion of insulating material and forming an interconnection between the selected ones of the metal silicide contacts and selected gate electrodes.

15. The method of claim 12 wherein the dummy gate electrodes comprise polycrystalline silicon and wherein the method further comprises depositing and planarizing a layer of polycrystalline silicon filling the openings after forming the metal silicide contacts.

16. The method of claim 10 wherein the semiconductor substrate comprises a plurality of conductivity-determining impurity doped regions separated by shallow trench isolation, the method further comprising forming at least some of the openings overlying the shallow trench isolation.

17. The method of claim 10 wherein planarizing the conductive material further comprises planarizing the conductive material to provide contacts for coupling the pull down transistors to a first potential node and coupling the pull up transistors to a second potential node.

18. The method of claim 10 wherein planarizing the conductive material further comprises planarizing the conductive material to provide contacts for coupling the first of the two pass gate transistors to a bit line, the second of the two pass gate transistors to a complementary bit line and gates of the two pass gate transistors to a word line of the SRAM integrated circuit.

19. The method of claim 10 wherein forming dummy gate electrodes comprises depositing a dummy gate electrode material overlying a high dielectric constant material and a layer of titanium nitride and wherein depositing a conductive material comprises depositing a layer of aluminum.

20. An SRAM integrated circuit comprising:
a first pull up transistor and a first pull down transistor each having a first common gate electrode formed of a conductive layer and coupled at a first node by the conductive layer;
a second pull up transistor and a second pull down transistor each having a second common gate electrode formed of the conductive layer and coupled at a second node by the conductive layer;
a first pass gate transistor having a third gate electrode formed of the conductive layer and coupled to the first node by the conductive layer;
a second pass gate transistor having a fourth gate electrode formed of the conductive layer and coupled to the second node by the conductive layer;
a first connection formed of the conductive layer between the first common gate electrode and the second node; and
a second connection formed of the conductive layer between the second common gate electrode and the first node.
